(19) United States
(12) Patent Application Publication
(10) Pub. No.: US 2014/0043012 A1
(43) Pub. Date: Feb. 13, 2014

(54) Apparatus and method for sampling a signal

(71) Applicant: VEGA Grieshaber KG, Wolfach (DE)

(72) Inventors: Michael Fischer, Alpirsbach (DE); Bernhard Corbe, Schutterwald (DE)

(73) Assignee: VEGA Grieshaber KG, Wolfach (DE)

(21) Appl. No.: 13/754,348

(22) Filed: Jan. 30, 2013

Related U.S. Application Data
(60) Provisional application No. 61/596,504, filed on Feb. 8, 2012.

(30) Foreign Application Priority Data
Feb. 8, 2012 (EP) 12 154 563.6

(51) Int. Cl. G01R 19/00

(52) U.S. Cl. CPC G01R 19/00
USPC 324/76.11; 327/92

(57) ABSTRACT

The sampling of a signal is described using a sampling bridge, the sampling terminals of which are interconnected.

### REFERENCE TO RELATED APPLICATIONS

This application claims the benefit of the filing date of EP Patent Application Serial No. EP 12 154 563.6 filed 8 Feb. 2012 and U.S. Provisional Patent Application Ser. No. 61/596,504 filed 8 Feb. 2012, the disclosures of both applications are hereby incorporated by reference.

### TECHNICAL FIELD

The present invention relates to the field of signal processing for measurement technology. In particular, the invention relates to measurement according to the transit time measurement principle, for example in a level measuring instrument, a limit measuring instrument or in a measuring instrument which uses the principle of guided microwaves. The present invention may relate to a sampling apparatus, a measuring instrument comprising a sampling apparatus, a method for sampling a signal, a computer-readable storage medium having a program for executing the method for sampling a signal and a program product for executing the method for sampling a signal.

The presentation entitled “Low-Cost Sampling Down Converter for UWB Sensor Applications” by Alexander Reisenzahn et al., Johannes Kepler University Linz, Institute of Microelectronics, discusses sequential sampling and the generation of sampling pulses.

In electrical engineering, the sequential sampling method is used in various applications. However, it is restricted to periodically recurring signals. Sequential sampling is used, inter alia, in sampling oscilloscopes and is employed in level measurement technology. Unlike real time sampling, sequential sampling gets along with a lower sampling frequency and, during sampling, converts the original signal to a lower frequency. A plurality of sampling circuits is available for this purpose.

Document DE 10 2005 024 643 A1 relates to a sampling circuit for sequentially sampling a broadband periodic input signal, where a non-linear component is provided which is supplied with a pulse-shaped sampling signal. A field effect transistor is provided as the non-linear component.

The document “Sampling Notes” by Tektronix Inc., S. W. Millikan Way, P.O. Box 5000 Beaverton, Oreg., revision 1.0. 13 Jan. 2009 describes concepts and systems for sampling oscilloscopes and in particular sequential sampling.

The document “Sampling Oscilloscope Techniques”, Tektronix, Technique Primer 47W-7209, 1989, describes different sampling concepts.

The document “Schottky Diodes for High Volume, Low Cost Applications”, Application Note 942, Hewlett Packard, May 1973 describes a sampling gate with four diodes.

There may be a need to enable a signal to be sampled efficiently.

### SUMMARY OF THE INVENTION

A description may be provided of a sampling apparatus, a measuring instrument comprising a sampling apparatus, a method for sampling a signal, a computer-readable storage medium having a program for executing the method for sampling a signal and a program product for executing the method for sampling a signal.

According to one aspect of the present invention, a sampling apparatus is described which comprises a sampling bridge, a first passive component and a second passive component. The sampling bridge comprises at least two diodes, each of the diodes having an anode and a cathode. The at least two diodes are connected in series and form a first branch of the bridge. Said first bridge branch is formed by connecting the anode of one diode to the cathode of the other diode at an input terminal. A second branch of the sampling bridge is formed by connecting at least two passive bridge components in series, an output terminal may be formed as the result of a coupling connection in the series connection of the at least two passive bridge components. The connection site, junction or coupling connection of the at least two diodes of the first bridge branch may form an input terminal. Accordingly, the first branch of the bridge may also be called the input branch and the second branch of the bridge may be called the output branch.

The substantially symmetrically constructed bridge branches are connected in parallel to form the sampling bridge, so that a free anode of a diode of the first bridge branch may be connected to a free end of a passive bridge component of the second bridge branch at a positive sampling terminal. A free cathode of a diode of the first bridge branch may be connected to a free end of another passive bridge component of the second bridge branch at a negative sampling terminal.

The output terminal, the input terminal, the positive sampling terminal and the negative sampling terminal may be formed by the construction of the sampling bridge between the described components at the respective junctions or connection sites, for example between the diodes or between the passive bridge components. A diode can be an embodiment of a passive bridge component. A terminal (connection) which can be formed between the components can have a contact surface.

A passive component which is used to form the sampling bridge may be termed a passive bridge component to express that it is to be associated with the sampling bridge.

A terminal (link) of a component which is not used to realise a bridge branch by a series connection of components may be termed a free end of a component. In one example, a terminal (link) may be a connecting wire, a bonding wire, a connecting end, a terminal foot or a “terminal pin” of a component.

A first terminal of the first passive component is connected to the positive sampling terminal of the sampling bridge and a first terminal of the second passive component is connected to the negative sampling terminal of the sampling bridge.

A second terminal of the first passive component is connected to a second terminal of the second passive component so that the two second terminals have a common potential or the same potential.

In different embodiments, the passive components or passive bridge components may be a resistor, a coil, a diode and/or a filter structure.

The first passive component and/or the second passive component may be adapted to produce a galvanic connection or an electrical connection to the earth terminal, to the common reference potential or to the circuit earth. Thus, for example a resistor or a coil can be used as a first passive component and/or as a second passive component, but basically not a capacitor.

A sampling bridge can alternatively also be called a sampling gate.

Due to the symmetrical construction of the sampling bridge from parallel-coupled branches which may be constructed with serially connected components of the same type, this sampling bridge can be termed a symmetrical sampling bridge or a symmetrically constructed sampling bridge.

According to another aspect of the present invention, a further sampling apparatus which realises the technical concept of the invention may have a single sampling bridge branch with at least one passive bridge component and with at least one diode.

With a construction of this type, a free end of the passive bridge component may have an input terminal and another end of the passive bridge component may be connected to an anode of the at least one diode. In this construction of the sampling bridge, a cathode of the at least one diode may have an output terminal.

The output terminal may be connected to a negative sampling terminal, to a first terminal of a capacitor and to a first terminal of a passive component. A second terminal of the capacitor and a second terminal of the passive component may be connected such that the two terminals have a common potential, for example an earth potential of the sampling apparatus.

Because of the construction of the sampling bridge of the further sampling apparatus having a reduced number of components with a passive bridge component and a diode may result in an asymmetrical construction of the sampling bridge or may result in an asymmetrical sampling bridge. Further embodiments of this sampling apparatus having an asymmetrical sampling bridge may be configured according to the configurations of the sampling apparatus having a symmetrical sampling bridge.

According to another aspect of the present invention, a method is described for sampling a signal by means of the sampling apparatus according to the invention. The method provides that the signal to be sampled is applied at the input terminal of a sampling bridge of a provided sampling apparatus. The method further comprises the provision of a first sampling signal at a positive sampling terminal of the sampling apparatus and substantially comprises at the same time the provision of a second sampling signal at the negative sampling terminal of the sampling apparatus. In order to provide a signal at a terminal, the corresponding terminal may be supplied with a corresponding signal.

The method also comprises the provision of an output signal at an output terminal of the sampling apparatus. Finally, the positive sampling terminal is discharged via the first passive component of the sampling apparatus and the negative sampling terminal is discharged via the second passive component to a common potential of the first passive component and of the second passive component.

In another embodiment a method for sampling a signal by means of the asymmetrical sampling bridge may be provided. The method may provide that the signal to be sampled is applied at the input terminal of the reduced sampling bridge. At the point in time when this signal to be sampled should be sampled, a sampling signal may be provided at the negative sampling terminal, for example also via a capacitor to suppress the direct current. Due to the negative sampling signal, the diode may conduct for the duration of the presence of the negative sampling signal and the signal to be sampled may be provided as a sampled output signal at the output terminal or at the negative sampling terminal. The capacitor which is present at the output terminal may store the output signal, in particular a charge corresponding to the output signal and, after the negative sampling signal has ceased, the passive component may ensure a charge equalisation of a charge stored on the capacitor for suppressing the direct current. The sampled signal can be provided as an output signal at the output terminal of the reduced bridge circuit.

According to another aspect of the present invention, a measuring instrument is described which comprises a transmit/receive device, a sampling apparatus according to the invention and a signal processing device to determine a measured value.

According to another aspect of the present invention, a computer-readable storage medium is described, on which a program code is stored which, when executed by a processor, executes at least one of the methods according to the invention for sampling a signal using a sampling apparatus.

According to another aspect of the present invention, a computer program product is described which, when executed by a processor, executes at least one of the methods for sampling a signal using a sampling apparatus.

In other words, the program which is stored on the computer-readable storage medium or the program product may control the sampling apparatus such that the corresponding method for sampling a signal is executes. In particular, the sampling apparatus may be controlled by the program or by the program product.

An idea of the invention may be that by briefly applying a single sampling signal or by applying a positive sampling signal and a negative sampling signal of the same magnitude substantially at the same time at a sampling bridge, the sampling bridge will briefly be made conductive and thus the signal to be sampled which is momentarily present at the input of the sampling bridge can be copied or reflected to an output of the sampling bridge and stored there, in order to be further processed within a sufficient period of time. While the stored signal is being evaluated, the sampling bridge may be substantially blocked such that an equalisation of the charge produced by the sampling signal to an earth connection or to a common reference potential is possible. However, a connection between output and input of the sampling bridge may be prevented during said evaluation. Dissipation of the charge of the stored signal may be substantially prevented.

The substantially parallel arranged bridge branches of the symmetrical sampling bridge may be constructed to be substantially symmetrical. The symmetrical construction may mean that the same number of diodes and/or of passive components is used in each of the bridge branches. In this construction, the same number of diodes and of passive components in the parallel bridge branches may also be termed symmetrical. In particular, the diodes may be arranged parallel in substantially the same direction or orientation, in particular based on the transmission direction or forward direction thereof. Directly interconnecting the second terminals of the passive components, without substantially connecting other components or voltage sources inbetween, may result in these terminals having a common or the same electrical potential. The joined terminals or the connected terminals, in particular the surfaces of the joined connections, may consequently form an equipotential surface. If this common potential is a ground potential, the two terminals have ground potential or earth potential. By connecting the terminals of the passive components, the diodes of the sampling bridge are operated in a substantially unbiased manner, i.e. without bias. Avoidance of the bias voltage may render the generation, processing or preparation and monitoring of a corresponding bias voltage superfluous. In particular, for example a positive or negative bias voltage may be omitted. The passive components, for example a resistor, an inductance or a filter structure can conduct charges away which are present on the negative sampling terminal and/or on the positive sampling terminal, to the common reference potential. By increasing the number of diodes in the respective bridge branches, the threshold voltage within a portion of a bridge branch can be increased in order to sample high input signals which may be fed to the input terminal.

A very sensitive point may arise at the output terminal of the sampling bridge. In other words, this may mean that a disturbance which may affect this sensitive point or this area of the sampling apparatus can distort the output signal to a very considerable extent. The provision of an amplifier at the output terminal may prevent an intervention of this type or an interference of this type on the sensitive point, if an intervention or interference of the circuit only takes place behind the amplifier or downstream of the amplifier.

The amplification of the signal at the output terminal of the sampling bridge by the amplifier may suitably prepare the sampled signal for further signal processing. In particular, the amplification may ensure an adequately high signal level.

The output terminal of the sampling bridge may denote a sensitive point of the circuit, since signals with a very low amplitude can arise at the output terminal. The weak signals can arise, because the echoes received from the surface of the charged material or from the surface of the bulk material and thereby the signals to be sampled are often considerably weakened. Amplification of these weak signals is useful for further signal processing.

Thus, intervention or interference at the sensitive area could significantly distort the weak signals by introducing a disturbance. This disturbance would then be amplified by the following amplifier to the same extent as the useful signal. For this reason, an intervention or interference may be meaningful only in the signal direction behind or downstream of the first amplifier, because here the echo signal is already amplified and the same disturbance can no longer distort the signal to such a great extent. Accordingly, it may also be sensible or useful to keep the development of disturbances at the sensitive point low, because the disturbances would have been amplified to the same extent.

According to a further aspect of the present invention, the at least two passive bridge elements are realised as at least two diodes.

The use of the diodes as passive bridge components may describe a sampling apparatus which comprises a sampling bridge, a first passive component and a second passive component. The sampling bridge comprises at least four diodes, each diode having an anode and a cathode. At least two of the diodes are connected in series and form a first branch of the bridge. The first bridge branch is formed by connecting the anode of one diode to the cathode of the other diode at an input terminal. A second bridge branch is formed accordingly in that at least two further diodes are connected in series where, in said series connection, the anode of the one further diode of the second bridge branch is connected to the cathode of the other further diode of the second bridge branch at an output terminal. Thus, the junction or connection site of the diodes of the first bridge branch may form the input terminal or input connection and the junction or connection site of the further diodes of the second bridge branch may form the output terminal or output connection. Accordingly, the first bridge branch may also be termed the input branch and the second bridge branch may be termed the output branch.

The substantially symmetrically constructed bridge branches are connected in parallel to form the sampling bridge, so that an anode of a diode of the first bridge branch is connected to an anode of a diode of the second bridge branch at a positive sampling terminal. A cathode of a diode of the first bridge branch is connected to a cathode of a diode of the second bridge branch at a negative sampling terminal.

A first terminal of a first passive component is connected to the positive sampling terminal and a first terminal of the second passive component is connected to the negative sampling terminal.

A second terminal of the first passive component is connected to a second terminal of the second passive component, so that the two second terminals have a common potential or have the same potential. The second terminals may substantially be directly interconnected, so that substantially no further components are connected between the second terminals.

According to one embodiment of the present invention, the common potential is an earth potential. In this case, the second terminals of the passive components may be termed earth terminals.

The earth potential may be a reference potential or an earth potential which is defined for the entire sampling apparatus and can be used for all the components of the sampling apparatus. The direct connection of the positive sampling terminal or of the negative sampling terminal by a passive component to the earth potential can prevent bias voltages and can be used to dissipate or discharge a charge which is present at the positive sampling terminal and/or at the negative sampling terminal. In other words, the joining of the terminals of the passive components may result in an equalisation of charges on the sampling terminals and may prevent such charges of a different polarity from remaining or existing over a relatively long period of time or from remaining static.

According to a further exemplary embodiment of the present invention, at least one diode from a bridge branch may be formed of at least two diodes which are connected in series. In other words, a single diode which is present may be replaced by at least two diodes so that a bridge branch can have, for example, three, four or a plurality of serially connected diodes. In one example, the number of diodes used per bridge branch may be even. A high input signal may be able to be processed as a result of increasing the number of diodes and the series connection, associated therewith, of the threshold voltages thereof.

According to a further exemplary embodiment of the present invention, a capacitor is connected at the output terminal. A terminal of the capacitor may be connected to the common reference potential, for example to the earth potential, and the other terminal of the capacitor may be connected to the output terminal or to the sensitive point of the sampling circuit.

The capacitor or charging capacitor can additionally stabilise the output voltage, provided substantially without direct voltage or free from direct voltage, however the capacitor may substantially not be used as a filter to remove alternating components. The charges which are stored on the capacitor may be very small and may require high amplification for further processing. The capacitor may be used as a holding element or as a retaining element. In other words, during the sampling procedure, i.e. while the sampling bridge is conductive, charge can flow from the input of the sampling bridge via the interconnected diodes onto the holding capacitor or retaining capacitor. After the sampling procedure when the diodes in the bridge are disabled again, the charge may be substantially maintained on the capacitor until the next sampling time. During this time, the drop in voltage across the holding capacitor or over the retaining capacitor may be further processed or detected.

According to another exemplary embodiment of the present invention, a differential amplifier is connected at the output terminal.

The differential amplifier may be connected to a pre-amplifier. The differential amplifier may form part of a control device or a regulation device which is used to compensate or equalize a direct voltage superimposed on the output signal.

In general, a terminal may be termed a connection, a clamp or a connection clamp. A terminal may be an apparatus for connecting an electronic component or another apparatus.

According to yet another exemplary embodiment of the present invention, a control device or a regulation device may be present at the output terminal, which control device may make it possible to remove or to compensate an offset voltage in the output signal. The control device may be connected in particular to the differential amplifier, so that the amplifier and/or the differential amplifier may be positioned between the output terminal of the sampling bridge and of the control circuit.

The control device may be configured as an automatic offset control device which uses the disconnection or switching off of the transmitter in order to determine and to compensate the current offset value or disturbance value. To determine the offset in predeterminable time ranges, the control device may switch off the transmitter or the transmit/receive device of a measuring instrument. The offset value may be compensated in the control device by feeding back an actuating variable and/or by digital offsetting in a digital signal processing device.

According to a further exemplary embodiment of the present invention, the control device comprises a digital/analog converter (D/A converter), an analog/digital converter (A/D converter) and/or a digital potentiometer.

According to yet another exemplary embodiment of the present invention, the sampling apparatus comprises a further sampling bridge.

The provision of a further sampling bridge can compensate thermal effects, for example, which act in a substantially similar manner on the at least two sampling apparatuses. In addition to or as an alternative to the control device, the second sampling bridge may be used to eliminate a superimposed direct voltage in the output signal, i.e. to eliminate an offset in the output signal. The offset may be substantially caused by an asymmetry in the sampling signals and can be compensated by the second bridge. This compensation is also carried out by temperature, since both sampling bridges are substantially of the same construction and also behave in substantially the same manner over temperature, through temperature or over a temperature range.

According to yet another exemplary embodiment of the present invention, the diodes of the sampling bridge are Schottky diodes.

A computer-readable storage medium may be a floppy disc, a hard disc, a USB (universal serial bus) storage medium, a RAM (random access memory), a ROM (read only memory) or an EPROM (erasable programmable read only memory). A computer-readable storage medium can also be a communications network, such as the Internet, which allows a program code to be downloaded.

It should be noted that different aspects of the invention have been described with respect to different subject-matter. In particular, some aspects have been described with respect to apparatus claims, while other aspects have been described with respect to method claims. However, a person skilled in the art will be able to discern from the description provided above and from the following description that, apart from when indicated otherwise, in addition to any combination of features which belongs to a category of subject-matter, any combination of features which relates to different categories of subject-matter is also considered as being disclosed by this text. In particular, combinations of features of apparatus claims and features of method claims are disclosed.

### BRIEF DESCRIPTION OF THE FIGURES

In the following, further exemplary embodiments of the present invention will be described with reference to the figures.

FIG. 1 shows a block diagram of an arrangement for sampling a signal, comprising a sampling bridge, where a bias voltage is present to gain a clearer understanding of the present invention.

FIG. 2 shows a block diagram of an arrangement for sampling a signal, comprising a symmetrical sampling bridge with a common reference potential according to an embodiment of the present invention.

FIG. 2a shows a block diagram of an arrangement for sampling a signal, comprising a further symmetrical sampling bridge with a common reference potential according to an embodiment of the present invention.

FIG. 3 shows a block diagram of an arrangement for sampling a signal, comprising a sampling bridge with a common reference potential and double diodes according to an embodiment of the present invention.

FIG. 4 shows a block diagram of an arrangement for sampling a signal, comprising a sampling bridge with a common reference potential and an output-side differential amplifier according to an embodiment of the present invention.

FIG. 5 shows a block diagram of an arrangement for sampling a signal, comprising a sampling bridge with a common reference potential and an output-side control circuit according to an embodiment of the present invention.

FIG. 6 shows a block diagram of an arrangement for sampling a signal, comprising a double sampling bridge with a common reference potential according to an embodiment of the present invention.

FIG. 7 shows a block diagram of a measuring instrument, comprising a sampling apparatus according to an embodiment of the present invention.

FIG. 8 shows a flow chart of a method for sampling a signal, having a sampling apparatus according to an embodiment of the present invention.

FIG. 9 shows a block diagram of an arrangement for sampling a signal, comprising an asymmetrical sampling bridge according to an embodiment of the present invention.

### DETAILED DESCRIPTION OF EMBODIMENTS

The sampling apparatus may be realised as an arrangement for sampling a signal or as a sampling circuit comprising a sampling bridge.

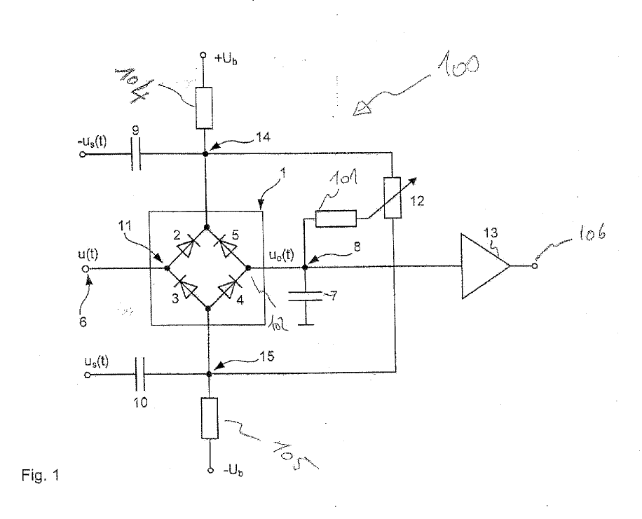

The illustrations in the figures are schematic and not to scale. In the following description of FIGS. 1 to 9, the same reference numerals are used for the same or corresponding elements.

FIG. 1 is a block diagram of an arrangement for sampling a signal, comprising a sampling bridge, where a bias voltage is present to gain a clearer understanding of the present invention.

FIG. 1 shows a sampling circuit 100 with a symmetrical diode bridge 1 or a symmetrical sampling bridge 1, comprising a total of four switching diodes 2, 3, 4, 5. The four diodes 2, 3, 4, 5 are negatively biased in the idle state or rest state of the circuit between the sampling times by the voltages, which are substantially identical in terms of amount and have a different polarity +U_{b} and −U_{b} via resistors 104, 105 and are consequently blocked. Due to the bias voltage, the passive components 104, 105 have a potential which differs from the reference potential. The bias voltage in the reverse direction of the diodes of the sampling bridge 1 can substantially prevent a possibly applying input signal, which is shown in FIG. 1 as a time t-dependent input signal u(t), from transferring the switching diodes 2, 3 into the conductive state. The time-dependent signal u(t) can be an alternating current signal (AC). The term “alternating current signal” can be understood as meaning a sinusoidal signal, although it does not necessarily have to be a sinusoidal signal. Instead, sequential sampling is suitable for any periodic input signal u(t).

At the time of sampling, the pulse-shaped sampling signals or pulse-form sampling signals which are shown in FIG. 1 as time-dependent positive sampling signal uₛ(t) and as time-dependent negative sampling signal −uₛ(t), move the switching diodes 2, 3, 4, 5 into the conductive state. The positive sampling signal uₛ(t) and the negative sampling signal −uₛ(t) may be substantially the same signals, according to amount, with inverted signs. The connection between the input clamp 6 and a charging capacitor 7 or the output terminal 102 or the output connection 102 by the sampling bridge 1 becomes low resistive, so that the capacitor 7 can be charged or discharged by the input voltage u(t). After the sampling procedure, the diodes 2, 3, 4, 5 are blocked again and the charge on the capacitor 7 is maintained approximately until the next sampling time. The output voltage uₒ(t) results as a temporally average drop in voltage across the charging capacitor 7 and can be tapped at the circuit node 8.

The input signal u(t) and the output signal uₒ(t) or the output voltage uₒ(t) at the sampling bridge 1 are periodic signals.

The two pulse-shaped sampling signals or the two pulse-form sampling signals uₛ(t) and −uₛ(t) are supplied via two capacitors 9, 10 which are used for DC decoupling. The DC decoupling substantially blocks a direct current (DC). Based on the earth potential, the two sampling signals are substantially identical in terms of amount and are inverse to one another, i.e. they are present with different polarities. These signals are generated, for example by a balancing unit or by a balun which is not shown in FIG. 1. As a result of the present symmetry in the circuit, the two sampling signals uₛ(t) and −uₛ(t) are substantially eliminated at the circuit nodes 8 and 11, i.e. the sampling clock is substantially isolated from the input or output of the circuit.

The isolation of the clock signal from the output may help in that the clock signal uₛ(t) and −uₛ(t) cannot be measured at the output of the circuit 1, although it is used in the circuit 1, for example to connect the diodes through or to enable the diodes. The isolation can be realised, for example, by appropriate circuitry measures. In the embodiment according to FIG. 1, the clock signal is eliminated by cancelling the two symmetrical components uₛ(t) and −uₛ(t) at output 8 or at input 11.

Using the sampling circuit 100 from FIG. 1, a substantially direct voltage-free or offset-free output signal uₒ(t) is generated at the circuit node 8 and at output terminal 102 of the sampling bridge 1. The circuit node 8 and the output terminal 102 are interconnected. A requirement for the generation of the direct voltage-free or offset-free output signal at the circuit node 8 is again the substantially prevailing circuit symmetry of the sampling bridge itself or the symmetry of the two sampling signals or timing signals uₛ(t) and −uₛ(t). However, in an actually realised circuit, it may be difficult, due to tolerances and parasitic elements of the components which are used of the sampling apparatus, to generate completely symmetrical sampling signals uₛ(t) and −uₛ(t). Furthermore, component tolerances, for example in the switching diodes 2, 3, 4, 5 can result in an imbalance in the sampling bridge 1. Both effects, asymmetries in the sampling signals and/or in the components result in an asymmetry of the sampling and appear, inter alia, by a direct voltage superimposed on the output signal uₒ(t) (DC symmetry) and by different signal amplitudes of the output signal uₒ(t), depending on the polarity of the input signal u(t) (AC symmetry). The direct voltage superimposed on the output signal uₒ(t) (DC symmetry) or the offset voltage is consequently also present in a construction with asymmetries, if only the sampling clock uₛ(t) and −uₛ(t) is present, but no input signal u(t).

Fed in by means of the potentiometer 12 at the output 8 of the sampling bridge 1 is a voltage which counteracts the undesired direct voltage or the offset due to a lack of symmetry, which voltage is superimposed on the output signal uₒ(t), compensates this and thus can slightly improve the symmetry of the sampling. The potentiometer 12 is adjusted manually and is adapted manually to the presently prevailing undesired direct voltage in regular time intervals. In the circuit shown in FIG. 1, the intervention or the interference takes place at the output node 8 immediately before or upstream of the intermediate frequency amplifier 13 and can result in marked effects behind or downstream of the intermediate frequency amplifier 13 at the output 106. The output node 8 is the most sensitive point of the sampling apparatus 100. This area 8 of the sampling apparatus is susceptible to the irradiation of interfering signals, for example due to crosstalk. The feeding-in of a direct voltage at the output 8 immediately before or upstream of the intermediate frequency amplifier 13 can lead to an impairment of the signal integrity.

In other words, the potentiometer 12 can change the direct voltage offset or DC offset of the sampled signal. In the amplifier 13, the sampled signal is amplified before being further processed. Non-compensated offset portions or offset components are also amplified and can significantly affect the further processing of the sampled signal due to the high amplification factor of the amplifier 13.

It is also possible for a plurality of sampling circuits 100 to be present in which solely field effect transistors and not diodes are used as non-linear circuit elements. This solution can be realised technically. However, it should be noted that field effect transistors which are suited to the higher microwave range are generally very expensive and, for example, can exceed the costs of high frequency diodes which can also be used in this frequency range.

In FIG. 1 a circuit 100 to compensate the sampling asymmetry was provided, which in reality substantially always occurs. Compensation is performed using the resistor 101 which is connected to the sliding contact of a potentiometer 12 and to the output node 8. The two external contacts of the potentiometer 12 are connected to the negative sampling terminal 14 or to the negative sampling connection 14 and to the positive sampling terminal 15 or to the positive sampling connection 15. The output node 8 is connected to the output terminal 102 of the sampling bridge 1. However, in this respect, intervention must take place at the output node 8 of the sampling bridge 1. The output node 8 is substantially the most sensitive point of the circuit and can be susceptible to the irradiation of interfering signals, for example due to crosstalk. Therefore, the feeding-in of a direct voltage at the output 8 immediately before the intermediate frequency amplifier 13 is impossible in many cases due to signal integrity.

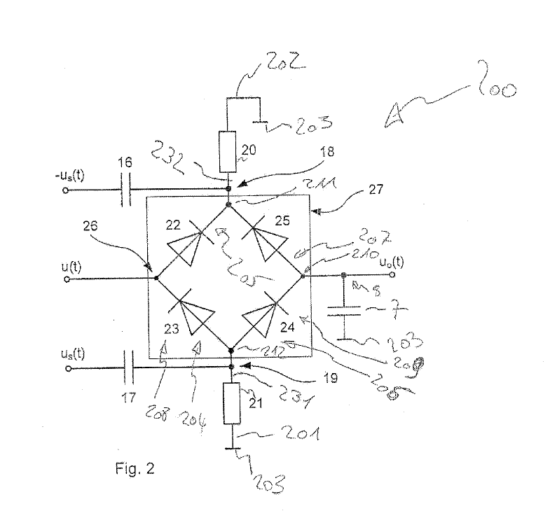

FIG. 2 shows a block diagram of an arrangement for sampling a signal, comprising a symmetrical sampling bridge with a common reference potential 203 according to an embodiment of the present invention. In the circuit 200 in FIG. 2, the diodes 22, 23, 24, 25 in the sampling bridge 27 are operated without bias voltage. A device for offset correction is not provided in the arrangement according to FIG. 2. For operation without bias voltage, the second terminals 201, 202 of the first passive component 21 and of the second passive component 20 are substantially directly connected to a common reference potential 203. Consequently, the second terminals 201, 202 are directly interconnected. As a result of this direct connecting, it is possible to dispense with the generation, processing and monitoring of the two voltages +U_{b} and −U_{b}, shown in FIG. 1. The first terminal 231 of the first passive component 21 is connected to the positive sampling terminal 212 and the first terminal 232 of the second passive component 20 is connected to the negative sampling terminal 211. The terminals 202, 232, 231, 203 of the passive components 20, 21 can be line elements. The two passive components 20, 21 make it possible for the capacitors 16 and 17 to discharge in the idle state between the sampling times. The passive components 20, 21 can be realised by two resistors 20, 21 which are arranged between the circuit nodes 18, 19 and the circuit earth 203. Removing the resistors 20, 21 could impair the operation of the circuit 200. Instead of the resistors 20, 21, inductances or filter structures, for example, can also be used. The circuit node 18 is connected to the first terminal 232 of the second passive component 20 and to the negative sampling terminal 211. The circuit node 19 is connected to the first terminal 231 of the first passive component 21.

The sampling bridge 27 has four portions 204, 205, 206, 207, each with a single diode 22, 23, 24, 25. Two serially connected portions in each case form a bridge branch 208, 209. The first bridge branch 208 is formed by the series connection of the diodes 22 and 23, the anode of diode 22 being connected to the cathode of diode 23. The second bridge branch 209 is formed by the series connection of diodes 25 and 24, the anode of diode 25 being connected to the cathode of diode 24.

The junction of diodes 22 and 23 or the connection site of diodes 22 and 23 forms the input terminal 26 and the junction of diodes 25 and 24 forms the output terminal 210.

The negative sampling terminal 211 is formed at the junctions of the cathodes of diodes 22 and 25 of the first bridge branch 208 and of the second bridge branch 209, respectively.

The positive sampling terminal 212 is formed at the junctions of the anodes of diodes 23 and 24 of the first bridge branch 208 and of the second bridge branch 209, respectively.

The negative sampling signal −uₛ(t) is conducted via the negative sampling terminal 211 and via a capacitor 16 or decoupling capacitor 16 to the sampling bridge 27 and the positive sampling signal uₛ(t) is conducted via the positive sampling terminal 212 and via a capacitor 17 or decoupling capacitor 17 to the sampling bridge 27.

In order to be able to sample greater input signals without negatively biasing the diodes in the sampling bridge 27, the use of a plurality of serially connected diodes is provided in the individual portions 204, 205, 206, 207 of the branches 208, 209 of the sampling bridge 27.

Economical Schottky diodes 22, 23, 24, 25 are used in the sampling bridge 27 as circuit elements and can be employed specifically for high frequency applications up into the microwave range on account of their low saturation capacities. The diodes 22, 23, 24, 25 in the sampling bridge 27 are not operated in a negatively biased manner by two direct voltages +U_{b} and −U_{b}. The diodes are thus operated in an unbiased manner or bias-free. Avoiding the positive and the negative bias voltage helps in being able to omit the generation, processing and monitoring of the two voltages +U_{b} and −U_{b}. By omitting the bias voltages the sampling circuit 27 can be constructed and operated in a simple manner. However, the sampling circuit 200 is adapted such that the capacitors 16 and 17 can discharge in the idle state between the sampling times, because they are charged to a certain extent by the pulse-shaped sampling signals uₛ(t) and −uₛ(t) and by the prevailing input voltage u(t) in each sampling period. This discharging can be controlled by passive components 20, 21, for example by two resistors 20, 21 which are arranged between the circuit nodes 18 and 19 and the circuit earth 203. The components of the sampling circuit 200 are dimensioned or configured such that the capacitors 16 and 17 are discharged substantially independently of the charging or discharging of the capacitor 7 by the input signal u(t). During dimensioning, the capacitances of the capacitors 16 and 17 and the values of the resistors 20 and 21 are adjusted to the pulse-shaped sampling signals. The amplitude, pulse length and pulse repetition frequency of the sampling signals play a major role in the dimensioning or calculation of the component values.

A possible dimensioning of the capacitors and resistors provides that an almost complete discharge of the capacitors 16 and 17 is achieved between the sampling times.

A further possible dimensioning which is also used in the case of measuring instruments focuses on the circuit node 18, at which the negative sampling pulses act, being charged to a slightly positive voltage value. In contrast to this, the circuit node 19, at which the positive sampling pulses act, must be charged to a slightly negative voltage value.

In this further dimensioning, the charges on the capacitors 16 and 17 and thus the voltages at the points 18 and 19 are also maintained in the idle state of the circuit between the sampling times or sampling time points and they act like a bias voltage of the diodes 22, 23, 24 and 25 in the reverse direction or in the disabling direction.

However, limits are imposed on the choice of capacitances and resistances, i.e. the values for the capacitor and for the resistor. For example, the capacitances, i.e. the capacitors 16 and 17, will be chosen to be high enough to allow the sampling pulses to pass through without relatively great distortions.

Furthermore, the resistors 20, 21 must be chosen to be high enough such that the sampling signals are not excessively loaded and, consequently, the sampling efficiency is not excessively impaired. In other words, the resistors 20, 21 may be chosen high enough because of the fact that large resistors do not excessively load the sampling signals and thus the sampling efficiency is not excessively impaired.

FIG. 2 shows the realisation of this circuit design 200 with the sampling bridge 27. In a further design or configuration, instead of the resistors 20 and 21, for example inductances or filter structures such as low-pass filters can also be used which produce a DC connection or a direct current connection from the circuit nodes 18 and 19 to the circuit earth 203 and discharge the capacitors 16 and 17 in the idle state between the sampling times. The circuit nodes 18 and 19 can be considered as an extended positive sampling terminal 212 and negative sampling terminal 211.

By applying the pulse-shaped sampling signals uₛ(t) and −uₛ(t) via the decoupling capacitors 16, 17 at the negative sampling terminal 211, 18 and at the positive sampling terminal 212, 19, the diodes 22, 23, 24, 25 of the sampling bridge 27 become conductive and, comparably to a short circuit, substantially connect the input terminal 26 and the output terminal 210 so that during the time the sampling signals uₛ(t) and −uₛ(t) are applied with a value above the threshold voltages of the diodes, the signal u(t) appears as an output signal uₒ(t). After the sampling signals uₛ(t) and −uₛ(t) have been applied, the connection between input terminal 26 and output terminal 210 is substantially blocked again.

Schottky diodes are available in various configurations for the microwave range. They are differentiated, inter alia, according to the level of their threshold voltage which is also termed flux voltage. High threshold voltages are reached in the case of what are known as “high barrier diodes” and are within a range of 0.65 to 0.7 V. The missing negative bias voltage of the diodes 22, 23, 24, 25 can result in disturbing influences during processing of high input signals u(t).

If the input signal u(t) to be sampled exceeds the threshold voltage of the type of diode used, the diodes 22 or 23 become conductive at the input node 26 or input terminal 26 even in the absence of sampling signals uₛ(t) and −uₛ(t), a fact that can impair the symmetry of the circuit and can disturb the mode of operation of the sampling of signal u(t). In order to also be able to sample greater input signals u(t) without negatively biasing the diodes 22, 23, 24 and 25 in the sampling bridge 27, the use of a plurality of serially connected diodes is provided in the individual branches of the sampling bridge 27.

FIG. 2a shows a block diagram of an arrangement 200′″ for sampling a signal, comprising a further symmetrical sampling bridge with a common reference potential according to an embodiment of the present invention. Compared to the sampling bridge 27 in FIG. 2, the sampling bridge 27′″ comprises the passive bridge components 24′″, 25′″ in the bridge branch 209′″. The bridge components 24′″, 25′″ are contained in the portions 206′″, 207′″ of the bridge branch 209′″. The further sampling bridge 27′″ or the further sampling apparatus 27′″ substantially corresponds to the sampling bridge 27 of FIG. 2, although branch 209 differs from branch 209′″ in that branch 209′″ has passive bridge components 24′″, 25′″ which are realised in branch 209 as serially connected diodes 24, 25. The construction of the rest of the sampling bridge 27′″ is substantially symmetrical. The output terminal 210′″ substantially corresponds to the output terminal 210.

The symmetrical sampling bridges 27, 28, 27′″ may be sampling bridges having substantially symmetrically arranged components. In spite of the symmetrically arranged components, asymmetries or non-symmetries can occur in the electrical characteristics, which can result in direct voltage offsets.

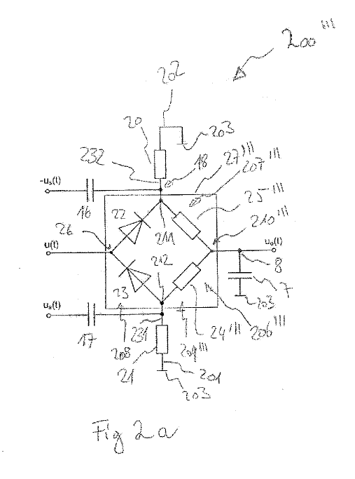

FIG. 3 shows an embodiment with, in each case, two serially connected diodes 22′, 22″, 23′, 23″, 24′, 24″, 25′, 25″ per branch in the sampling bridge 28. In an arrangement of this type with in each case double diodes 22′, 22″, the input signal u(t) is substantially restricted to a maximum of double the threshold voltage of the type of diode which is used.

FIG. 3 shows a block diagram of an arrangement 300 for sampling a signal, comprising a sampling bridge 28 with a common reference potential and double diodes according to an embodiment of the present invention. Thus, FIG. 3 shows an embodiment of the circuit of FIG. 2 with two serially connected diodes per portion 204, 205, 206, 207 of the first branch 208 and of the second branch in the sampling bridge 28. In this case, the input signal is substantially restricted to a maximum of double the threshold voltage of the type of diode used. Diode 22 with the single threshold voltage is replaced by the two diodes 22′ and 22″ each with the single threshold voltage, which single threshold voltages are totalled to produce double the threshold voltage in portion 205. Diode 23 with the single threshold voltage is replaced by the two diodes 23′ and 23″ each with the single threshold voltage, which single threshold voltages are totalled to produce double the threshold voltage in portion 204. Diode 25 with the single threshold voltage is replaced by the two diodes 25′ and 25″ each with a single threshold voltage, which single threshold voltages are totalled to produce double the threshold voltage in portion 207. Diode 24 with the single threshold voltage is replaced by the two diodes 24′ and 24″ each with a single threshold voltage, which single threshold voltages are totalled to produce double the threshold voltage in portion 206.

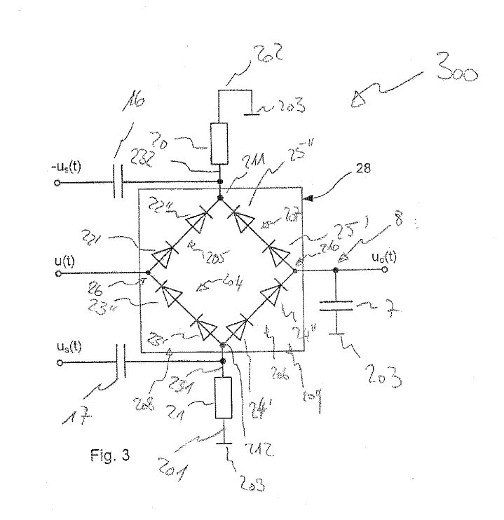

FIG. 4 shows a block diagram of an arrangement for sampling a signal, comprising a sampling bridge 27, 28 with a common reference potential 203 and an output-side differential amplifier 31 according to an embodiment of the present invention. The sampling bridge 27, 28 in FIG. 4 can be a symmetrical or an asymmetrical bridge. FIG. 4 shows a sampling circuit 400 which substantially waives the intervention or the interference at the substantially most sensitive point 8 of the circuit at output 210 of the sampling bridge 27, 28 and thus can improve the interference resistance of the arrangement. The signal u(t) to be sampled is fed to the sampling bridge 27, 28 at the input terminal 26. In spite of waiving or dispensing with the intervention at the sensitive point 8, i.e. in spite of waiving the direct action on the sampled signal uₒ(t), the circuit 400 can compensate the direct voltage superimposed on the output signal uₒ(t). In other words, interference may only take place behind or downstream of the amplifier 30. The sampled signal uₒ(t) or the output signal uₒ(t) is provided at the output clamp 210 or at the output terminal 210 of the sampling bridge 27, 28. From there, the sampled signal passes to the amplifier 30 which substantially isolates the output 401 from the sensitive point 8 and amplifies the possibly small output signal uₒ(t). The direct voltage superimposed on the output signal uₒ(t) is compensated or equalized by a second amplifier 31 which is configured as a differential amplifier and is arranged in a signal flow direction downstream of the first intermediate frequency amplifier 30. The differential amplifier 31 is positioned closer to the output 401 than the intermediate frequency amplifier 30.

Consequently, FIG. 4 shows a circuit 400 which waives the intervention at the sensitive point 8 of the circuit directly before or upstream of the first intermediate frequency amplifier 30 and nevertheless is still capable of compensating the direct voltage superimposed on the output signal uₒ(t). In other words, the compensation of the superimposed direct voltage means an offset correction. To compensate the direct voltage, a second amplifier 31 is used, which is configured as a differential amplifier and is arranged in a signal propagation direction downstream of the first intermediate frequency amplifier 30. The output signal uₒ(t) of the sampling bridge 27, 28 is initially delivered to the first IF amplifier 30 (intermediate frequency amplifier 30) with the undesired superimposed direct voltage and is amplified there. In a second step, the signal is delivered to a positive input 34 of the differential amplifier 31. Supplied at the second input 35 of the differential amplifier is a direct voltage which for example, as can be seen in FIG. 4, can be adjusted within particular limits with the potentiometer 33 via a voltage divider 32 and a resistor 404. The voltage divider 32 also comprises the two dividing resistors 402, 403. Also in arrangement 400, manual adjustment and manual tracking of the compensating voltage is required. The differential amplifier 31 forms a weighted difference of the signals at both inputs 34 and 35 thereof and generates an output signal u_{d}(t) at the output 401. Consequently, it is possible to compensate the direct voltage superimposed on the output signal uₒ(t) and to generate a direct voltage-free output signal u_{d}(t).

Furthermore, with the circuit arrangement of FIG. 4, a defined direct voltage portion or a direct voltage component can be deliberately superimposed on the output signal u_{d}(t) of the differential amplifier 31. The sampling bridge 27, 28 can be a symmetrically constructed sampling bridge 27, 28. However, the output uₒ(t) can also be an output of an asymmetrically constructed sampling bridge.

However, with the arrangement of FIG. 4, it is substantially impossible to influence the sampling asymmetry, which often occurs in reality. This asymmetry can be caused by non-ideal components. Non-ideal components are impaired by tolerances and parasitic elements. The circuitry or the interconnection according to FIG. 4, in particular the arrangement of amplifier 30 and differential amplifier 31, can compensate the effect of the asymmetry which has been produced, i.e. it can compensate the direct voltage offset. The sampling asymmetry which occurs can be kept within justifiable limits with the construction of the sampling bridge 27, 28 according to FIG. 4 and by a careful choice of the components of the circuit arrangement 400, particularly of the switching diodes in the sampling bridge 27, 28 and of the balun (not shown in FIG. 4) to generate the sampling signals uₛ(t) and −uₛ(t) and can be used for applications in level measurement technology.

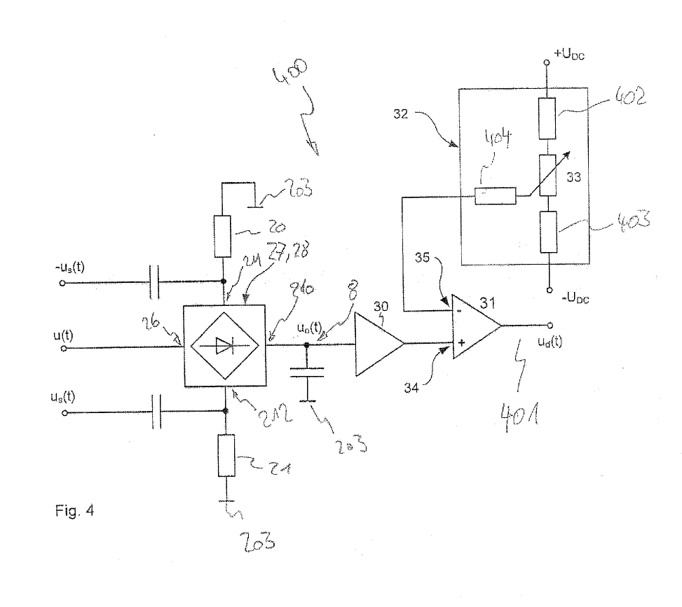

FIG. 5 shows a block diagram of an arrangement 500 for sampling a signal, comprising a sampling bridge 27, 28 with a common reference potential 203 and an output-side control circuit 501 according to an embodiment of the present invention. The sampling bridge 27, 28 can be a symmetrically constructed sampling bridge 27, 28. However, the output uₒ(t) can also be an output of an asymmetrically constructed sampling bridge. FIG. 5 shows a sampling circuit 500 which generates a substantially direct voltage-free output signal u_{d}(t) at the differential amplifier 38 in an automated manner using a control device 501. When ambient temperatures change, this circuit 500 can be used appropriately within a wide temperature range. Alternatively, the output signal u_{d}(t) can also be superimposed in a defined manner with a direct voltage.

The control device 501 comprises the calculation unit 36 or the processor 36, the analog-digital converter 41 (A/D converter), the digital-analog converter 37 (D/A converter) and the differential amplifier 38. The output signal u_{d}(t) of the differential amplifier 38 is returned to the positive input 39 of the differential amplifier 38 via the A/D converter 41, the calculation unit 36 and the D/A converter 37. In the calculation unit 36 or the offset determining apparatus 36, an offset is determined during an artificially generated idle phase by switching off a transmitting device or a transmit/receive device of a measuring instrument (not shown in FIG. 5). The disturbing offset can be compensated promptly with this offset value which is substantially present at the determining moment. Manual intervention to compensate the offset, as for the adjustment of the potentiometer 33, may be avoidable by the automatic offset compensation by the control circuit 501.

The output signal uₒ(t) is delivered via an amplifier 30 and via the negative input 40 of the differential amplifier 38 to the differential amplifier 38. The automatic control loop 501 or the control device 501 replaces the manual direct current compensating device 32 of FIG. 4.

As described, in the control device 501, a substantially direct voltage-free output signal u_{d}(t) can be generated or the output signal u_{d}(t) can be superimposed in a defined manner with a direct voltage portion in an automated manner as an alternative to the manual adjustment using potentiometers 12, 33. In detail, the control device 501 takes or taps the output signal u_{d}(t) and generates therefrom an actuating variable in the form of a voltage for the differential amplifier 38. This branched-off output signal u_{d}(t) is delivered via an ND converter 41 to the calculation unit 36, for example, which checks the signal for a direct voltage component in that the calculation unit 36 compares the digitalised signal u_{d}(t) with a reference value. In turn, the calculation unit 36 controls the digital-analog converter 37 which generates an output voltage which is delivered to the positive input 39 of the differential amplifier 38 and is able to compensate the direct voltage component of the signal u_{d}(t), thereby producing an output signal u_{d}(t) which is free from a direct voltage component or free from a direct voltage portion. In this procedure, the offset of u_{d}(t) is corrected. The direct voltage component which is already present in the signal uₒ(t) cannot be substantially influenced by the control device 501. The direct voltage component of the output signal uₒ(t) of the sampling bridge 27, 28 will change in particular over the change in temperature and can be compensated by means of the described control device 501 so that a substantially direct voltage-free output signal u_{d}(t) is present at the output 502 over the entire relevant temperature range in which the circuit 500 is operated.

Instead of a digital-analog converter 37, a digital potentiometer, for example, can also be used which is controlled by the calculation unit 36.

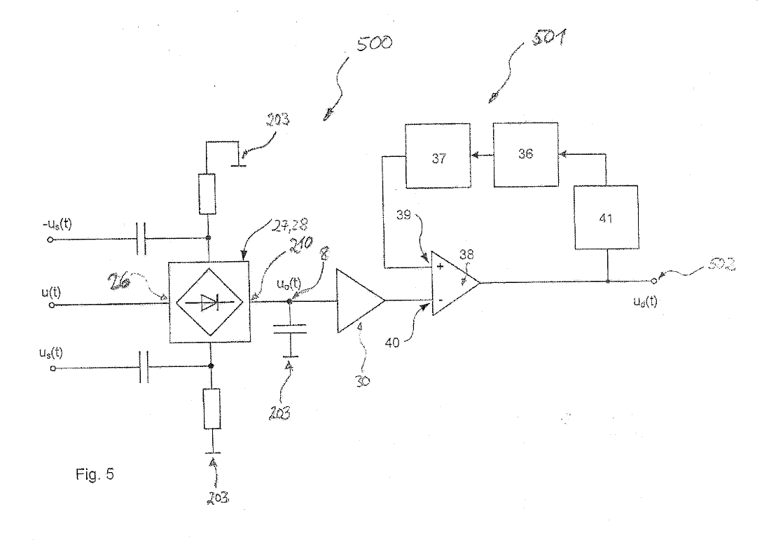

FIG. 6 shows a block diagram of an arrangement 600 for sampling a signal, comprising a double sampling bridge 27, 28, 27′, 28′ with a common reference potential according to an embodiment of the present invention. The sampling bridge 27, 28, 27′, 28′ can be a symmetrically constructed sampling bridge 27, 28, 27′, 28′. However, these sampling bridges can also be asymmetrically constructed sampling bridges or any combination of symmetrically constructed sampling bridges and asymmetrically constructed sampling bridges. Finally, FIG. 6 shows a sampling circuit 600 having two symmetrically constructed sampling bridges 27, 28, 27′, 28′, which can generate an almost direct voltage-free output signal u_{d}(t) at the output 610 particularly over the temperature without a control device.

In other words, the arrangement of the main sampling bridge 27, 28 and of the side sampling bridge 27′, 28′ or secondary sampling bridge 27′, 28′ may substantially compensate the influence of a variable temperature profile on the output signal u_{d}(t). In contrast to the embodiments of FIGS. 4 and 5 with respectively only a single sampling bridge, two substantially identically constructed sampling bridges 27, 28, 27′, 28′ are used in the arrangement 600. The two sampling bridges are configured, for example as a single bridge circuit 27, 27′ or as a double bridge circuit 28, 28′. i.e. as a bridge circuit 28 with in each case two or a plurality of diodes 22′, 22″, 23′, 23″, 24′, 24″, 25′, 25″. Both sampling bridges 27, 28, 27′, 28′ are controlled by the same sampling signals uₛ(t) and −uₛ(t), the input signal u(t) substantially only being delivered to the first sampling bridge 27, 28 or main sampling bridge 27, 28. The second sampling bridge 27′, 28′ is terminated at its input 26′ or at its input terminal 26′ by a resistor 44. The terminating resistor 44 can be selected such that the input terminal 26′ is terminated in a substantially reflection-free manner. The construction of the arrangement 600 with the use of an asymmetrically constructed sampling bridge substantially corresponds to this construction described for the symmetrically constructed sampling bridge, wherein the terminals 19, 19′ and thus the positive sampling signal uₛ(t) are omitted, so that substantially only the negative sampling signal −uₛ(t) exists.

When the sampling signals uₛ(t) and −uₛ(t) are delivered to the sampling nodes 18, 19 or 18′, 19′, adequate isolation should be provided between the two sampling bridges 27, 28, 27′, 28′. When common sampling nodes 18, 18′ or 19, 19′ are used, it could happen that the positive sampling nodes 19, 19′ or the negative sampling nodes 18, 18′ are not adequately isolated from one another. Node 18 should be isolated from node 18′ and node 19 should be isolated from node 19′. In an embodiment, care should be taken that the sampling bridges 27, 28 and 27′, 28′ are not directly interconnected by the lines 601 and 603 or 601′ and 603′. In other words, attention should be paid to a galvanic isolation between lines 601 and 601′ and to an electrical isolation between lines 603 and 603′. During the generation of the sampling signals, attention should be paid as soon as possible in the signal chain or as much in front as possible in the signal chain to an isolation of the sampling signals for both sampling bridges. For example, an early isolation can take place in a signal flow direction upstream of a balun 707 (not shown in FIG. 6). In other words, each sampling bridge may have its own allocated balun. In one example, the lines or conductors 601 and 601′ or 603 and 603′ can be of substantially the same length. In another example, in which the lines 601 and 601′ or 603 and 603′ are not of the same length, the arrangement should be configured such that the signal amplitudes, arriving at the two sampling bridges, of the sampling signals in the lines 601, 601′, 603, 603′ are substantially identical. Different signal propagation times, caused, for example by different line lengths, can be accepted, since merely one direct voltage offset is compensated which forms on temporal average.

The main sampling bridge 27, 28 provides the main output signal uₒ₁(t) and the side sampling bridge 27′, 28′ or the secondary sampling bridge 27′, 28′ provides the side output signal uₒ₂(t) or the secondary output signal uₒ₂(t). The two output signals uₒ₁(t) and uₒ₂(t) of the sampling bridges 27, 28, 27′, 28′ are delivered to a differential amplifier 45 which forms the difference of the two signals and at the same time amplifies it. For this purpose, the main output terminal 210 is connected to the negative input of the differential amplifier 45 via the node 8 which is connected to the capacitor 7, and the side output terminal 210′ or the secondary output terminal 210′ is connected to the positive input of the differential amplifier 45 via the node 8′ which is connected to the capacitor 7′. Both output signals uₒ₁(t) and uₒ₂(t) have substantially the same direct voltage component. The output signal u_{d}(t) of the differential amplifier 45 is provided at the output 610. Since the two output signals uₒ₁(t) and uₒ₂(t) are provided at different inputs with different polarities, in the differential amplifier 45 the direct voltage components of the output signals uₒ₁(t) and uₒ₂(t) are cancelled out, which components are to be attributed to an asymmetry in the sampling signals uₛ(l) and −uₛ(t). A superimposed direct voltage at the output 210, 210′ which is itself caused by an asymmetry in the construction of the sampling bridge 27, 28 and/or is caused by an asymmetry in the construction of the sampling bridge 27′, 28′, for example due to different component tolerances, may however not be substantially compensated by the circuit arrangement 600. Thus, a superimposed direct voltage, itself caused by an asymmetry in the two sampling bridges 27, 28 or 27′, 28′, is maintained at the output 610, as long as the asymmetry is not mutually cancelled out by chance. An asymmetry in the two sampling bridges 27, 28 or 27′, 28′ can be caused, for example, by component tolerances or parasitic elements in the components or diodes. In other words, the asymmetries produced by the construction of the sampling bridges within the respective sampling bridge may lead to different offset voltages in the output signals uₒ₁(t) and uₒ₂(t). If these are subtracted in the differential amplifier, an undesirable superimposed residual voltage can remain in the signal u_{d}(t), if the errors due to the component tolerances do not cancel one another out.

According to one aspect of the invention, the sampling apparatus according to the invention can provide a sampling circuit for level measurement technology which is cost-effective, of a simple construction, is robust particularly in respect of signal integrity and is suitable for series production. The sampling apparatus 27, 28 or circuit arrangement 27, 28 according to the invention substantially avoids an intervention of a compensating circuit 12 in a signal direction upstream of the intermediate frequency amplifier 13, 30.

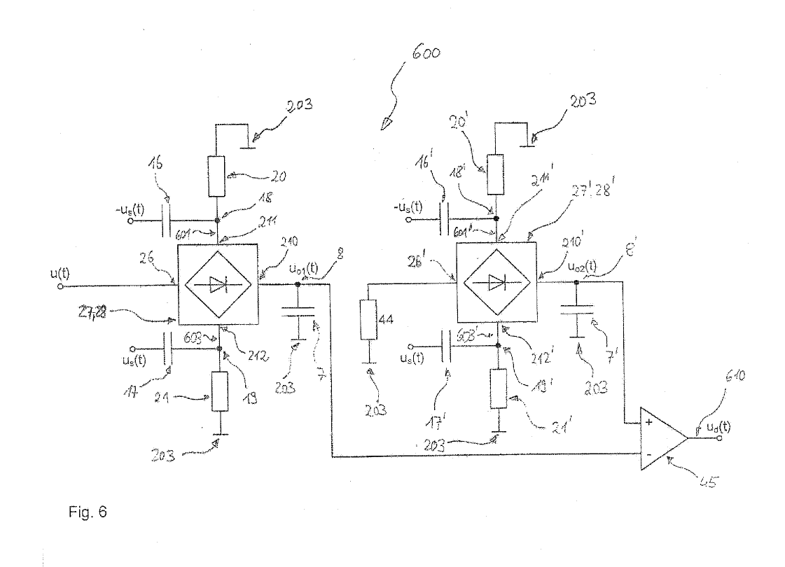

FIG. 7 shows a block diagram 700 of a measuring instrument 701, comprising a sampling apparatus 200, 300, 400, 500, 600 according to an embodiment of the present invention. The measuring instrument 701 has an antenna 702. If the principle of guided microwaves is used for level measurement, a coupling device, a feed-in device, activator or a coupling with a connected measuring probe can be used instead of the antenna 702. This antenna 702 or coupling is operated by the transmit/receive device 703, which generates and transmits a transmission pulse and receives a reflected signal. The reflected signal which is delivered to the sampling apparatus via the input terminal 26 is sampled in the sampling apparatus 200, 300, 400, 500, 600. The sampled signal is delivered to the signal processing device 704 via the output 210, 502, 610. After the signal has been processed, the signal processing device 704 provides a signal at the external interface 705, which signal corresponds to the determined measured value, for example a fill level. The transmit/receive device 703 comprises a transmission pulse generator 708 for generating a signal which is to be reflected at the surface to be measured. The measuring instrument 701 further comprises the sampling pulse generator 706 and the balun 707. The sampling pulse generator 706 generates the regular sampling pulse and the symmetry element 707 or the balun 707 converts the sampling pulse into the positive and/or negative sampling signal uₛ(t) and/or −uₛ(t), which is delivered to the appropriate sampling terminal via the capacitors 16, 17.

The measuring instrument 701 can be a level measuring instrument or a limit measuring instrument which uses free field propagation or the principle of guided microwaves in order to carry out a transit time measurement.

The measuring instrument which is shown in the block diagram of FIG. 7 uses a transmission pulse which is generated in the transmission pulse generator 708. Part of the transmission pulse or some of the energy of the transmission pulse passes directly to the input 26 of the sampling circuit 200, 300, 400, 500, 600 and is used as a reference signal. The other part arrives at the antenna 702 or at the measuring probe, when applying the guided microwave principle. This other part of the transmission pulse is transmitted. The pulse reflected at the surface of the bulk material then also passes to the input 26 of the sampling circuit 200, 300, 400, 500, 600 via the transmit/receive unit 703.

After the signals delivered to the sampler have been sequentially sampled in the sampling circuit 200, 300, 400, 500, 600, an echo curve is produced which is evaluated and further processed in the signal processing device 704.

The sampling circuit 200, 300, 400, 500, 600 can comprise the symmetrically constructed sampling bridges 27, 28.

The pulses for controlling or driving the sampling device or the sampling apparatus are generated in the sampling pulse generator 706, are balanced or made symmetrical in the balun 707 and then delivered to the sampling bridge.

However, in another embodiment, an asymmetrically constructed sampling bridge 900 can also be used. With a corresponding construction of a measuring instrument with the asymmetrical sampling bridge 900, it is possible to omit the balun 707, the capacitor 17 and the passive component 21 and the capacitor 7 is replaced by the capacitor 907.

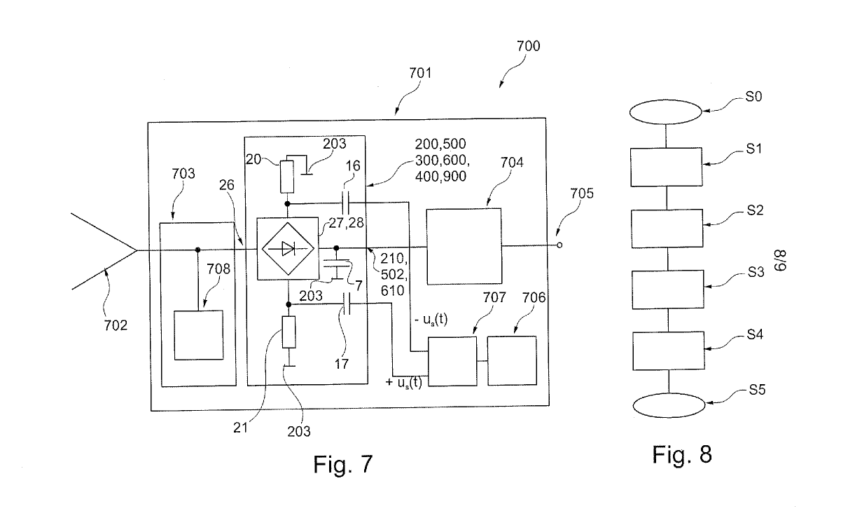

FIG. 8 shows a flow chart of a method for sampling a signal, using a symmetrically constructed sampling apparatus according to an embodiment of the present invention.

In step S1, coming out of the idle state S0, the signal to be sampled is applied at an input terminal 26 of a sampling bridge 27, 28 of a sampling apparatus 200, 300, 400, 500, 600.

In step S2, a first sampling signal +uₛ(t) is provided at a positive sampling terminal 212 of the sampling apparatus and a second sampling signal −uₛ(t) is provided at a negative sampling terminal 211 of the sampling apparatus. In one example, the first sampling signal +uₛ(t) and the second sampling signal −uₛ(t) are provided substantially parallel or simultaneously.

In step S3, an output signal uₒ(t) is provided at the output terminal 210 of the sampling apparatus 200, 300, 400, 500, 600 and in step S4, the positive sampling terminal is discharged via a first passive component of the sampling apparatus to a common potential and the negative sampling terminal is discharged via a second passive component to a common potential.

The method then ends in the idle state S5.

A method for sampling a signal using an asymmetrically constructed sampling apparatus merely provides in step S2 the generation of a first sampling signal −uₛ(t) at a negative sampling terminal of the sampling apparatus. Furthermore, in step S4, the negative output terminal 211″ is merely discharged to the common potential.

According to one aspect of the invention, the sampling of a signal is described using a sampling bridge 27, 28, the sampling terminal 211, 212 of which are interconnected.

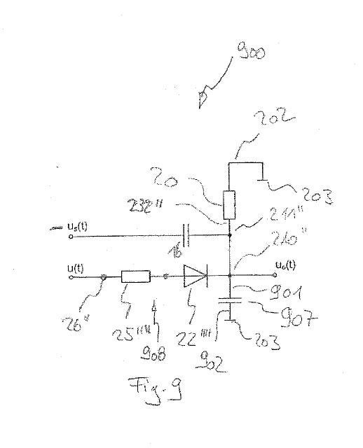

FIG. 9 shows a block diagram of an arrangement for sampling a signal, comprising an asymmetrically constructed sampling bridge according to an embodiment of the present invention.

The negative sampling signal −uₛ(t) is delivered via the capacitor 16 to the negative sampling terminal 211″ which substantially corresponds to the output terminal 210″. A sampling signal at the sampling terminal 211″ can switch the diode 22″″ and the resistor 25″″, which connect together the input terminal 26″ and the output terminal 210″ and form the bridge branch 26″, into a conductive state. In this conductive state, the signal u(t) to be sampled is forwarded to the output and in particular to the capacitor 907. There, it can be tapped and made available for signal processing. A suitable dimensioning of the components in the sampling circuit which is oriented towards the dimensioning of the sampling bridge 27, can ensure that the useful signal uₒ(t) is substantially not diverted via the resistor 20 to the circuit earth. The resistor 20 is substantially used to discharge the capacitor 16 which can be charged to a particular extent by the periodic sampling signal uₛ(t). The first terminal 232″ of the resistor 20 or of the passive component 20 is connected to the output terminal 210″ and to the first terminal 901 of the capacitor. The second terminal 202 of the resistor 20 is directly connected to the second terminal 902 of the capacitor 907.

In addition, it is pointed out that the terms “comprising” and “having” do not exclude any other elements or steps and “a” or “one” do not exclude a plurality. It is also pointed out that features or steps which have been described with reference to one of the above embodiments can also be used combined with other features or steps of other embodiments described above. Reference signs in the claims should not be construed as limiting the scope of the claims.

What is claimed:

1. A sampling apparatus, comprising:
a sampling bridge including at least two diodes, each of the at least two diodes including an anode and a cathode, the at least two diodes being connected in series and form a first bridge branch, so that the anode of one diode is connected to the cathode of the other diode at an input terminal;
a first passive component;
a second passive component; and
at least two passive bridge components connected in series and forming a second bridge branch, so that a connection between the at least two passive bridge components forms an output terminal;
wherein the first and second bridge branches are connected in parallel so that a free anode of a diode of the first bridge branch is connected to a free end of a passive bridge component of the second bridge branch at a positive sampling terminal; and a free cathode of a diode of the first bridge branch is connected to a free end of another passive bridge component of the second bridge branch at a negative sampling terminal;
wherein a first terminal of the first passive component is connected to the positive sampling terminal;
wherein a first terminal of the second passive component is connected to the negative sampling terminal;
wherein a second terminal of the first passive component is connected to a second terminal of the second passive component so that the two second terminals have a common potential.

2. The sampling apparatus of claim 1, wherein the at least two passive bridge components are at least two diodes.

3. The sampling apparatus of claim 1, wherein the common potential is an earth potential.

4. The sampling apparatus of claim 1, wherein at least one diode is formed from the series connection of at least two diodes.

5. The sampling apparatus of claim 1, wherein a capacitor is connected at the output terminal.

6. The sampling apparatus of claim 1, wherein at least one differential amplifier is connected at the output terminal.

7. The sampling apparatus of claim 1, wherein a control device is connected at the output terminal.

8. The sampling apparatus of claim 7, wherein the control device includes at least one of a digital/analog converter and a digital potentiometer.

9. The sampling apparatus of claims 1, further comprising:
a further sampling bridge.

10. The sampling apparatus of claims 1, wherein the at least two diodes of the sampling bridge are Schottky diodes.

11. A sampling apparatus, comprising
a sampling bridge branch including at least one passive bridge component and at least one diode;
wherein a free end of the at least one passive bridge component has an input terminal;
wherein another end of the at least one passive bridge component is connected to an anode of the at least one diode;
wherein a cathode of the at least one diode has an output terminal;
wherein the output terminal is connected to a negative sampling terminal, a first terminal of a capacitor and a first terminal of a passive component; and
wherein a second terminal of the capacitor and a second terminal of the passive component have a common potential.

12. A measuring instrument, comprising:
a transmit/receive device;
a sampling apparatus including (a) a sampling bridge including at least two diodes, each of the at least two diodes including an anode and a cathode; (b) a first passive component; (c) a second passive component; and (d) at least two passive bridge components; and
a signal processing device,
wherein the at least two diodes are connected in series and form a first bridge branch, so that the anode of one diode is connected to the cathode of the other diode at an input terminal;
wherein the at least two passive bridge components are connected in series and form a second bridge branch, so that a connection between the at least two passive bridge components forms an output terminal;
wherein the two bridge branches are connected in parallel so that a free anode of a diode of the first bridge branch is connected to a free end of a passive bridge component of the second bridge branch at a positive sampling terminal; and a free cathode of a diode of the first bridge branch is connected to a free end of another passive bridge component of the second bridge branch at a negative sampling terminal;
wherein a first terminal of the first passive component is connected to the positive sampling terminal;
wherein a first terminal of the second passive component is connected to the negative sampling terminal;
wherein a second terminal of the first passive component is connected to a second terminal of the second passive component so that the two second terminals have a common potential;
wherein the transmit/receive device is adapted to send a transmit signal and to receive a received signal;
wherein the transmit/receive device is adapted to provide the received signal at an input terminal of the sampling apparatus;
wherein the sampling apparatus is configured to provide an output signal via an output terminal of the sampling apparatus to the signal processing device; and
wherein the signal processing device is configured to determine and provide a measured value from the output signal.

13. A method for sampling a signal using a sampling apparatus of claim 1, comprising:
applying the signal at an input terminal of a sampling bridge of the sampling apparatus;
providing a first sampling signal at a positive sampling terminal of the sampling apparatus;
providing a second sampling signal at a negative sampling terminal of the sampling apparatus;
providing an output signal at the output terminal of the sampling apparatus; and
discharging the positive sampling terminal via a first passive component of the sampling apparatus and discharging a negative sampling terminal via a second passive component to a common potential.

14. A computer-readable storage medium on which a program is stored, wherein the program is adapted, when executed by a processor, to execute the method for sampling a signal using a sampling apparatus according to claim 13.

15. A non-transitory computer program product which is adapted, when executed by processor, to execute the method for sampling a signal using a sampling apparatus according to claim 13.
